(19) United States
(12) Patent Application Publication
(10) Pub. No.: US 2009/0058559 A1
(43) Pub. Date: Mar. 5, 2009

(54) MICROPROCESSOR COMMON-MODE EMISSIONS REDUCTION CIRCUIT

(76) Inventor: William F. Pakkala, Owosso, MI (US)

Correspondence Address: DELPHI TECHNOLOGIES, INC., M/C 480-410-202, PO BOX 5052, TROY, MI, 48007, US

(21) Appl. No.: 11/848,793

(22) Filed: Aug. 31, 2007

(51) Int. Cl. H03H 1/00

(52) U.S. Cl. 333/185

(57) ABSTRACT

An apparatus with reduced common-mode (CM) emissions from of a microprocessor includes a circuit board, first and second capacitors and a common-mode (CM) choke. The circuit board has a connector configured for connection to an external wire harness, which may act as an antenna generating CM RF emissions. The microprocessor includes a power pin (VCC), a ground pin (VSS), and at least one high impedance input pin. The first capacitor is connected across the power and ground pins. The second capacitor is connected across the high impedance input pin and the ground pin. The common-mode (CM) choke is electrically intermediate the power and ground pins, on the one hand, and the corresponding power and ground terminals of the connector on the other hand. The CM choke is disposed a preselected distance from the microprocessor. The preselected distance, which may be as close as possible, is configured to achieve an effective amount of common-mode emissions attenuation. The power and ground terminals are coupled to electrically conductive first traces on the circuit board, while the power and ground pins are coupled to electrically conductive second traces on the circuit board. The first traces are located outside a predefined isolation zone surrounding the second traces. The isolation zone is configured in size and shape so as to substantially minimize capacitive coupling between the second traces and the first traces.

### TECHNICAL FIELD

The present invention relates to a microprocessor common-mode (CM) emissions reduction circuit.

### BACKGROUND OF THE INVENTION

Electromagnetic interference (EMI) and radio frequency (RF) interference can be in general a significant problem for many electrical circuits. This problem has become more challenging to manage effectively as the use of electronics in all variety of products expands. An entire discipline has developed to address such problems, and a correspondingly wide variety of strategies and/or products have been developed, as seen for example by reference to U.S. Pat. No. 6,346,865 issued to Callewaert et al. entitled “EMI/RFI FILTER INCLUDING A FERROELECTRIC/FERROMAGNETIC COMPOSITE”, assigned to the common assignee of the present invention, and hereby incorporated by reference herein in its entirety.

In particular, in the automotive field, most if not all original equipment manufacturers (OEM) of trucks and automobiles require that electronic component manufacturers meet very strict radio-frequency (RF) emissions requirements. RF emissions requirements for electronic components help ensure that such a component installed on an OEM vehicle will not interfere with vehicle on-board radio performance. Additionally, RF emissions requirements may be specified by a government agency so it is important to the vehicle OEM that component design compliance to RF emissions standards be met.

Although there are a variety of circuit sources that produce RF emissions found in vehicle electronics (i.e., charge pumps, CAN communications, power switching, etc.), one source is a microprocessor, due to its internal construction which involves current switching (i.e., emissions emanate from the microprocessor die due to the short duration, relatively high current switching by a large number of individual transistors switching in synchronism according to a clock signal). As to microprocessors, the primary source of microprocessor RF emissions arise from common-mode (CM) RF currents.

Conventional approaches taken to control such common-mode RF emissions include the use of ferrites connected on the microprocessor power and ground pins, close placement of decoupling capacitors, isolated circuit board layout techniques and connector filtering. Additionally, conventional approaches for minimizing the entry of (as opposed to the emission of) common-mode noise into a circuit, such as employing a common-mode choke near an entry point of the circuit (e.g., as close as possible to an interface connector), and, conventional countermeasures to reduce differential-mode emissions, each have had only a minimal impact on reducing common-mode (CM) RF emissions. Thus, while some approaches have been somewhat effective in reducing common-mode RF emissions, meeting OEM test requirements continues to present challenges.

There is therefore a need for an apparatus for controlling common-mode (CM) RF emissions that minimizes or eliminates one or more of the problems described above.

### SUMMARY OF THE INVENTION

The present invention is directed to an apparatus for significantly reducing radiated RF emissions from an integrated circuit, such as a microprocessor, having a switching characteristic giving rise to the production of common-mode RF switching currents. If left uncontrolled, such currents can produce RF emissions The use of the present invention, however, can realize a 10-15 dB improvement (i.e., a reduction) in such common-mode RF emissions.

An apparatus having reduced common-mode RF emissions arising from operation of a switching device, for example a microprocessor, includes a circuit board, first and second capacitors and a common-mode (CM) choke. The circuit board has a connector configured for connection to an external wire harness, which may otherwise operate, in the absence of the present invention, as an antenna for generating RF emissions. In a preferred embodiment, the microprocessor is of the type that includes a power pin (VCC), a ground pin (VSS), and at least one high impedance input pin. The first capacitor is a decoupling capacitor and is connected across the power and ground pins of the microprocessor (i.e., as close as possible). The second capacitor is connected across the high impedance input pin and the ground pin of the microprocessor (i.e., again as close as possible). The common-mode (CM) choke is electrically intermediate the power and ground pins of the microprocessor, on the one hand, and corresponding power and ground terminals of the connector, on the other hand. The choke is operative to substantially cancel the common mode RF currents thereby reducing common mode RF emissions.

The CM choke is disposed a preselected distance from the microprocessor, preferably as physically close as possible. This close proximity is configured to achieve an effective level of common-mode RF emissions. The positioning of the CM choke improves the canceling effect as to the CM currents before significant emissions results. Additionally, the invention includes an isolation feature, which ensures effective control of the CM RF emissions. In this regard, the power and ground terminals of the connector are coupled to corresponding electrically conductive first traces disposed on the circuit board. The power and ground pins of the microprocessor are coupled to electrically conductive second traces disposed on the circuit board. The first traces are located outside a predefined isolation zone surrounding the second traces associated with the microprocessor. In a preferred embodiment, the isolation zone is configured in size and shape so as to substantially minimize capacitive coupling from the second traces to the first traces.

Other features, aspects and advantages of the present invention are also presented.

### BRIEF DESCRIPTION OF THE DRAWINGS

The present invention will now be described, by way of example, with reference to the accompanying drawings.

FIG. 1 is a schematic and block diagram of an apparatus according to the present invention, showing a circuit board with a microprocessor, a connector and common-mode (CM) emissions reduction features.

FIG. 2 is a diagrammatic view of an isolation zone separating power and ground foil traces on the circuit board generally from the traces associated with the power and ground pins of the microprocessor.

### DETAILED DESCRIPTION OF THE PREFERRED EMBODIMENT

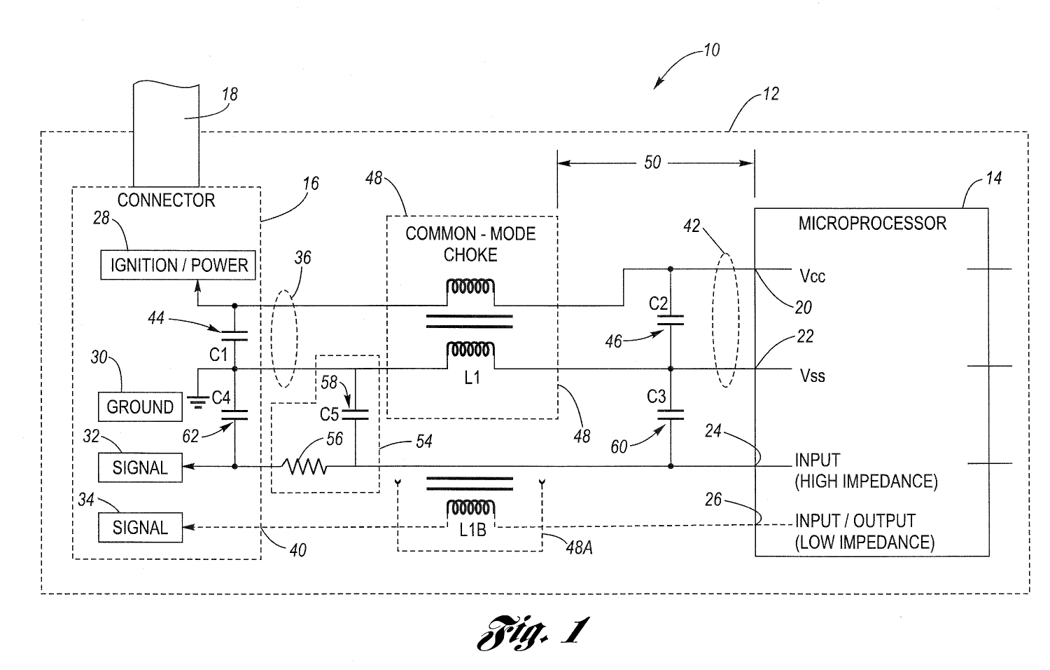

Referring now to the drawings, wherein like reference numerals are used to identify identical components in the various views, FIG. 1 is a schematic and block diagram of an electronic apparatus 10 including common-mode (CM) RF emissions reduction features according to the present invention. Apparatus 10 includes a main circuit board 12 on which is disposed an integrated circuit having electrical switching characteristics, such as a microprocessor 14, that is susceptible to producing CM RF currents, and hence CM RF emissions. FIG. 1 additionally shows circuit board 12 having a connector 16 located thereon configured for connection to an external wire harness 18 or the like. As described above, the present invention is directed to minimizing or eliminating RFI by addressing a principal source of such emissions, namely, microprocessor RF emissions. As to microprocessor RF emissions, the primary source involves common-mode (CM) RF currents. As one example, such CM RF currents occur in a microprocessor during short duration, high current switching conditions, such as an in phase pulse out of all pins connected to microprocessor die, or other general switching operations. As a further example, as known, a microprocessor may contain a very large number of transistors, significant numbers of which are arranged to be switched on/off in synchronism in accordance with a clock signal, thus also producing switched currents. These switching examples, which occur typically in the megahertz frequency range, create common-mode (CM) RF currents. A significant contributor to RF emissions from a microprocessor are those where the CM currents are allowed to propagate along low impedance lines, such as the power (Vcc) and ground (Vss) lines. In a typical automotive vehicle application, where microprocessor-based circuits communicate with other sub-systems, a wire harness is provided. The power and ground lines, thus coupled to the wire harness (e.g., wire harness 18), can complete an RF emissions system, where the harness acts as a transmitting antenna of the RFI. An effective measure according to the invention is to thus prevent the CM currents from reaching the wire harness in the first place. It should be appreciated that interference of this type may fall generally within the 10 to 400 MHz range.

Returning to FIG. 1, circuit board 12 may comprise conventional components and construction techniques known to those of ordinary skill in the art. For example, circuit board 12 may include a rigid or semi-rigid substrate including a plurality of power, ground and signal foil traces, arranged in single or multiple layers.

Microprocessor 14 may comprise a conventional, commercially-available component known to those of ordinary skill in the art. It should appreciated that while the illustrated embodiment is directed to controlling common-mode RFI originating with microprocessor 14, the present invention is not so limited, and may be usefully employed to control CM RF currents (and emissions therefrom) from a variety of switching circuits all having the common feature that they each are characterized by noise producing CM RF currents. For example, a microcontroller would also fall within the spirit and scope of the present invention.

Microprocessor 14 is an integrated circuit formed on a die and provided, conventionally, in a package suitable for mounting on circuit board 12. For clarity, the signal nodes external to microprocessor 14 will be described as “pins” while the signal nodes associated with connector 16 will be described as “terminals”. With this background, microprocessor 14 includes a power pin (Vcc) 20, a ground pin (Vss) 22, at least one or more high impedance input pins 24, and optionally one or more low impedance input/output (I/O) pins 26. Microprocessor 14 operates in accordance with a clock signal or signals (not shown), which typically provide for operation of microprocessor 14 in the megahertz frequency range, giving rise to CM originated RF emissions also in the megahertz frequency range (as described above).

Connector 16 may comprise conventional and commercially-available components. Connector 16 is configured to include a plurality of connection terminals corresponding to many of the pins of microprocessor 14 (as well as perhaps other components on board 12). Connector 16 may include (as shown) a power terminal 28, a ground terminal 30, an input (high impedance) signal terminal 32 and, optionally, an input/output (low impedance) signal terminal 34. Although power terminal 28 is shown as an “ignition” power terminal (i.e., as understood, a source of power that becomes active when the “ignition” key is turned on by an operator of a motor vehicle), it should be understood that the power terminal need not carry switched power and may be energized continuously.

Each of the terminals of connector 16 is configured for connection to a corresponding conductor (not shown) of wire harness 18. Additionally, power and ground terminals 28, 30 are configured for electrical connection to corresponding foil traces, hereinafter collectively referred to as “first traces” 36, that are disposed on circuit board 12. First traces are configured to carry power/ground to the various other components (other than microprocessor 14) on circuit board 12, as known in the art. High impedance input terminal 32 may also be connected to a trace 38 and low impedance I/O terminal 34, if present, may also be connected to a trace 40. Likewise, power (Vcc) and ground (Vss) pins 20, 22 of microprocessor 14 are configured for electrical connection to foil traces on board 12 and are collectively referred to as “second traces” 42.

With continued reference to FIG. 1, a number of common-mode noise reduction features of the present invention will now be described. A first capacitor 44 (also designated “C1” in FIG. 1) is electrically connected across power and ground terminals 28, 30 of connector 16. Specifically, one lead of capacitor 44 is connected to power terminal 28 and the other lead of capacitor 44 is connected to ground terminal 30. First capacitor 44 is a conventional bypass capacitor, non-polarized, which is preferably located as physically close to connector 16 as possible. Capacitor 44 may be a ceramic capacitor.

A second capacitor 46 (also designated “C2” in FIG. 1) is electrically connected across power and ground pins 20, 22. Specifically, one lead of capacitor 46 is connected to power pin 20 and the other lead of capacitor 46 is connected to ground pin 22. Capacitor 46 is a decoupling capacitor, which is located, preferably, as physically close to microprocessor 14 power/ground pins 20, 22 as possible, minimizing trace length. Capacitor 46 may be a ceramic capacitor.

A common-mode (CM) choke 48 is configured to suppress common-mode RF currents originating with microprocessor 14 that may otherwise propagate on low impedance pathways (e.g., the power and ground lines). Choke 48 is electrically intermediate the power and ground pins 20, 22 of microprocessor 14, on the one hand, and the corresponding power and ground terminals 28, 30 of connector 16, on the other hand. The CM choke 48 is disposed a preselected distance 50 from microprocessor 14, the distance being configured to achieve an effective amount of common-mode RF emissions attenuation. This is accomplished by achieving an effective amount of CM RF currents cancellation in the first instance by appropriate location of CM choke 48. In a constructed embodiment, choke 48 is preferably located as close as physically possible to the power and ground pins of microprocessor 14 to obtain the greatest degree of benefit. In one embodiment, an effective amount of CM RF emissions attenuation is no less than 3 dB of attenuation. In an alternate embodiment, the effective amount of CM RF emissions attenuation is no less than about 10 dB of attenuation. It should be understood that other embodiments are possible. CM choke 48 may comprise conventional, commercially available components. CM choke 48 may comprise a surface mount device (SMD).

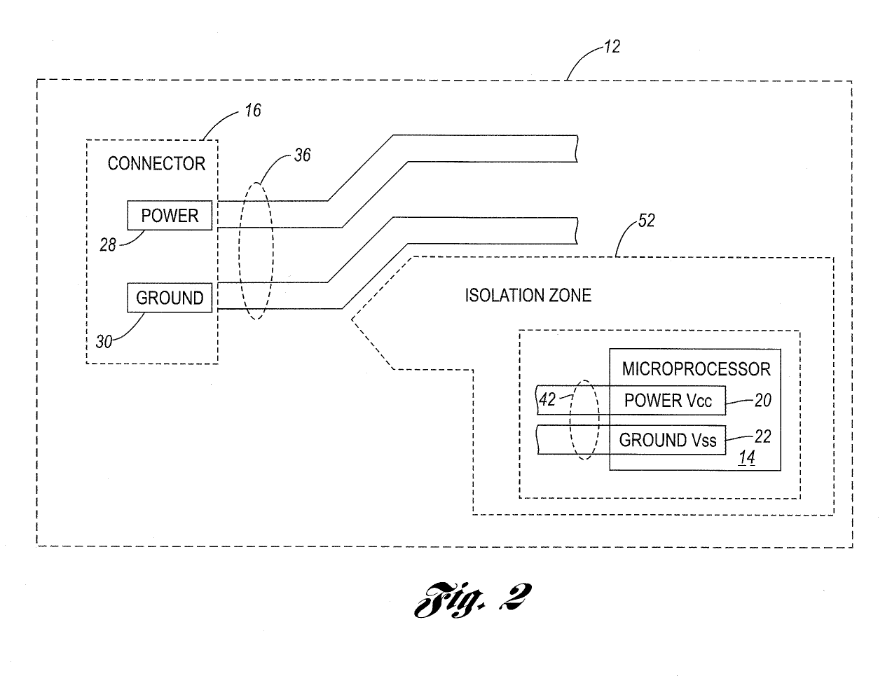

FIG. 2 is a diagrammatic view of circuit board 12 showing an isolation feature according to the invention. The first traces 36 associated with the power and ground terminals 28, 30 of connector 16 are outside of a predefined isolation zone 52 surrounding second traces 42 that are associated with power and ground pins 20, 22 of microprocessor 14. Isolation zone 52 is configured in size and shape so as to minimize capacitive coupling that may bridge CM choke 48, i.e., minimize common-mode RF currents on the Vcc and Vss traces 42 from capacitively coupling to first (connector) traces 36, where it could be transmitted by wire harness 18 acting as an antenna. The actual size and shape of isolation zone 52 in any particular embodiment is defined by the relevant operating parameters such as the frequency and amplitude of the common-mode currents originating from the operation of microprocessor 14, among other factors. Additionally, the respective sizes/shapes of traces 36, and traces 42 will also affect the degree of capacitive coupling, and thus the size and shape of the needed isolation zone. In the illustrated embodiment, the isolation zone 52 is configured so as to substantially surround, and preferably completely surround (i.e., contiguous) microprocessor 14. Accordingly, the foil traces 36 on the board 12 are arranged as a result so that the microprocessor is on an “island” when compared to the rest of the board circuitry.

With continued reference to FIG. 1, in an alternate embodiment, microprocessor 14 includes high-impedance input pin 24, which conventionally includes a filter, such as an RC filter 54 for analog noise filtering. As shown, a simplified representation of RC filter 54 may include (i) a resistor 56 (also designated “R1” in FIG. 1) in series between the input terminal 32 and input pin 24, and (ii) a capacitor 58 (also designated “C5” in FIG. 1) that is shunted to ground. For inputs that apply a slewed signal to microprocessor 14, a third capacitor 60 (also designated “C3” in FIG. 1) is provided and which is electrically connected between input pin 24 and ground pin 22. The addition of third capacitor 60 is to address and alleviate so-called “ground bounce” introduced by CM choke 48 so as to eliminate false triggering in microprocessor 14. In this alternate embodiment, a conventional bypass capacitor 62 (also designated “C4” in FIG. 1) is electrically connected between the signal terminal 32 and ground terminal 30. Capacitors 58, 60 and 62 may all be ceramic, non-polarized capacitors.

In a still further embodiment, at least one, and optionally a plurality, of additional low impedance input/output (I/O's) from connector 16 (e.g., low impedance I/O terminal 40) are connected to microprocessor 14 (e.g., I/O pin 26). In this alternate embodiment, CM choke 48 can be configured as a 3-way CM choke, diagrammatically shown as by the addition of a 1-way section 48a, which is to be considered and consolidated as part of CM choke 48 forming a three-way device. In this instance, section 48a shares its core with the core of CM choke 48, and has the same winding orientation. This concept is extensible for still further low impedance I/O terminals destined for connection to corresponding pins of microprocessor 14.

Example. In a constructed embodiment of FIG. 1, microprocessor 14 comprises an advanced integrated circuit device operating at a nominal operating frequency of 324 MHz. The CM choke 48 is a commercially available component, having model no. ACT45B-510-2P-TL003, from TDK. Choke 48 has a rated voltage of 50 V, a maximum DC resistance of 1 ohm, and a rated current of 200 amps. CM choke 48 is located approximately 5 mm from microprocessor 14. Bypass capacitors have capacitance of 0.01 μF and 0.1 μF, respectively. Decoupling capacitor 46 has a capacitance of 0.1 μF. Resistor 56 has a resistance of 2K ohms and capacitor 58 has a capacitance of 0.1 μF. In this embodiment, common-mode RF emissions were attenuated by an amount between about 10-15 dB over a frequency range of about 10-400 MHz.

The present invention, particularly the combination of the CM choke with appropriate isolation of power and ground pins, provides improved common-mode noise attenuation, exemplary reductions being observed in the 10-15 dB range.

While the invention has been described by reference to various specific embodiments, it should be understood that numerous changes may be made within the spirit and scope of the inventive concepts described. Accordingly, it is intended that the invention not be limited to the described embodiments, but will have full scope defined by the language of the following claims.

What is claimed is:

1. An apparatus comprising:
a circuit board having a connector configured for electrical connection to an external wire harness, said circuit board including an integrated circuit having internal current switching characteristics resulting in common-mode currents said integrated circuit having a power pin and a ground pin;
a first capacitor connected across said power and ground pins;
a common-mode (CM) choke electrically intermediate said power and ground pins of said integrated circuit and corresponding power and ground terminals of said connector, said CM choke being disposed a preselected distance from said integrated circuit, said distance being configured to achieve an effective amount of common-mode emission attenuation that would otherwise arise from said common-mode currents;
said power and ground terminals being coupled to corresponding electrically conductive first traces on said circuit board, said power and ground pins of said integrated circuit being coupled to corresponding electrically conductive second traces on said circuit board, said first traces being located outside a predefined isolation zone surrounding said second traces.

2. The apparatus of claim 1 wherein said integrated circuit comprises a microprocessor.

3. The apparatus of claim 2 wherein said microprocessor includes a high impedance input pin that is coupled to a corresponding input terminal of said connector by a filter, said apparatus further including:
a second capacitor connector across said ground pin and said input pin proximate said microprocessor.

4. The apparatus of claim 3 wherein said filter is an RC filter having a first resistor in series between said input pin and said corresponding input terminal of said connector and a third capacitor between said input pin and said ground terminal

5. The apparatus of claim 2 wherein said microprocessor includes a low impedance Input/Output (I/O) pin, said CM choke including a further pass-through to effect connection of said low impedance Input/Output (I/O) pin to a corresponding low impedance Input/Output (I/O) terminal on said connector, said apparatus including a further capacitor connected across said low impedance Input/Output (I/O) pin and said ground pin proximate said microprocessor.

6. The apparatus of 1 wherein said CM choke is a surface mounted device (SMD).

7. The apparatus of claim 1 wherein said common-mode noise is manifested in electromagnetic interference (EMI) in a frequency range of between about 10 to 400 MHz.

8. The apparatus of claim 1 wherein said apparatus further includes a bypass capacitor electrically connected across said power and ground terminals proximate said connector.

9. The apparatus of claim 1 wherein said effective amount of said common-mode emissions attenuation is at least 3 dB.

10. The apparatus of claim 9 wherein said effective amount of said common-mode emission attenuation is at least 10 dB.

11. The apparatus of claim 1 wherein said predefined isolation zone is selected in size and shape so as to substantially minimize capacitive coupling between said second traces to and first traces.

12. The apparatus of claim 11 wherein said isolation zone is defined as a function of a frequency and an amplitude of said common-mode currents.

13. The apparatus of claim 11 wherein said isolation zone substantially surrounds said microprocessor.

14. The apparatus of claim 11 wherein said isolation zone is contiguous and completely surrounds said microprocessor.
